(19) United States
(12) Patent Application Publication
(10) Pub. No.: US 2026/0255817 A1
(43) Pub. Date: Aug. 27, 2026

(54) DISPLAY SUBSTRATE, MASK PLATE AND EVAPORATION SYSTEM

(71) Applicants: CHONGQING BOE DISPLAY TECHNOLOGY CO., LTD., Chongqing (CN); BOE TECHNOLOGY GROUP CO., LTD., Beijing (CN)

(72) Inventors: Fei Shuai, Beijing (CN); Cheng Chen, Beijing (CN); Jongkyun Lee, Beijing (CN)

(73) Assignees: CHONGQING BOE DISPLAY TECHNOLOGY CO., LTD., Chongqing (CN); BOE TECHNOLOGY GROUP CO., LTD., Beijing (CN)

(21) Appl. No.: 18/993,820

(22) PCT Filed: May 17, 2024
(86) PCT No.: PCT/CN2024/094057

§ 371 Date: Jan. 13, 2025

(30) Foreign Application Priority Data
Jun. 20, 2023 (CN) 202310738734.9

(51) Int. Cl. H10K 59/131; C23C 14/04; H10K 59/122; H10K 71/16

(52) U.S. Cl. CPC H10K 59/131; C23C 14/042; H10K 59/122; H10K 71/166

(57) ABSTRACT

A display substrate, a mask plate and an evaporation system which relate to the technical field of displays. The display substrate comprises a substrate, the substrate comprising a display device region, and a non-display device region adjacent to the display device region, a light-emitting device layer located in the display device region, and at least one test unit located in the non-display device region and distributed in a planar direction of the display substrate, the test unit comprising multiple measurement areas disposed at intervals in the planar direction. Each measurement area in a test unit is used to test at least one layer located on the light-emitting device layer, and the number of measurement areas in the at least one test unit is no less than the number of film layers of the light-emitting device layer.

### CROSS-REFERENCE TO RELATED APPLICATION

The application claims the priority of the Chinese Patent application filed on Jun. 20, 2023 before the CNIPA, China National Intellectual Property Administration with the application number of 202310738734.9, and the title of “DISPLAY SUBSTRATE, MASK PLATE, AND EVAPORATION SYSTEM”, which is incorporated herein in its entirety by reference.

### FIELD

The present disclosure relates to the technical field of display, and particularly to a display substrate, a mask plate, and an evaporation system.

### BACKGROUND

In the manufacturing process of a display panel, for example, in the manufacturing process of an organic light emitting diode (OLED) display panel, various film layers of a light emitting device in the display panel are deposited on a base. Generally, the film layers in the panel need to be evaporated or deposited layer by layer. In practice, in order to ensure the yield of a product, it is required to know whether the thickness of each formed film layer meets the standard.

### SUMMARY

The present disclosure provides a display substrate, including: a display device area, and a non-display device area adjacent to the display device area; wherein
a light emitting device layer, located in the display device area;
at least one test unit, located in the non-display device area and distributed in a planar direction of the display substrate, the test unit comprising a plurality of measurement areas provided at intervals in the planar direction,
wherein each measurement area in one test unit is configured to test at least one layer located in the light emitting device layer, and the number of measurement areas in the at least one test unit is not less than the number of film layers comprised in the light emitting device layer.

Optionally, the display substrate further comprising: a substrate, a first electrode layer, and a pixel definition layer, wherein the first electrode layer is close to the substrate, and the pixel definition layer is located at a side of the first electrode layer facing away from the substrate,
wherein the pixel definition layer located in the display device area comprises a plurality of first openings arranged at intervals, and orthographic projections of the first openings on the substrate fall into an orthographic projection of the first electrode layer on the substrate;
the pixel definition layer located in the non-display device area comprises a plurality of second openings arranged at intervals, and the second openings form the measurement areas,
wherein the first electrode layer serves as an anode or a cathode in the light emitting device layer.

Optionally, the second opening is located at the side of the first electrode layer facing away from the substrate, and an orthographic projection of the second opening on the substrate falls into the orthographic projection of the first electrode layer on the substrate.

Optionally, a size of an orthographic projection of one of the second openings on the substrate is greater than a size of the orthographic projection of one of the first openings on the substrate.

Optionally, at least one of the measurement areas is provided with an emissive film layer in the light emitting device layer, and the display device area comprises a plurality of sub-pixels, wherein a size of an orthographic projection of the emissive film layer on the substrate is greater than a size of an orthographic projection of the sub-pixel on the substrate.

Optionally, the plurality of measurement areas are arranged in an array in the planar direction.

Optionally, the plurality of measurement areas comprise first measurement areas provided with first type film layers and second measurement areas provided with second type film layers, and the first measurement area is located at a side of the second measurement area facing away from the display device area.

Optionally, the first type film layers comprise a common film layer, and the second type film layers comprise an emissive layer.

Optionally, an orthographic projection of the first type film layer on a base of the display substrate completely covers the display device area, and an orthographic projection of the second type film layer on the base of the display substrate partially covers the display device area.

Optionally, the first type film layer comprises at least one of an electron injection layer, an electron transport layer, a hole injection layer, a hole transport layer, a hole barrier layer, an electron barrier layer, a charge generation layer, a second electrode layer, and a light extraction layer, and the second type film layer comprises the emissive layer and an auxiliary emissive layer.

Optionally, the number of measurement areas in the at least one test unit is greater than the number of film layers of the light emitting device layer,
wherein the plurality of measurement areas further comprise third measurement areas, and the third measurement areas are provided with a protective layer;
in the third measurement areas, the number of third measurement areas provided at the same side as the first measurement area is greater than the number of third measurement areas provided at the same side as the second measurement area.

Optionally, the at least one test unit is arranged in the non-display device area at equal intervals.

Optionally, the non-display device area comprises a first frame region and a second frame region oppositely provided in a first direction, and a plurality of test units are disposed in the first frame region and/or the second frame region.

Optionally, the plurality of test units are symmetrically disposed in the first frame region and the second frame region.

Optionally, the plurality of test units are disposed in the first frame region and the second frame region, wherein a straight line parallel to the first direction passes through one test unit located in the first frame region or passes through one test unit located in the second frame region.

Optionally, the plurality of test units are disposed in the first frame region and the second frame region, wherein a straight line parallel to the first direction simultaneously passes through one test unit located in the first frame region and one test unit located in the second frame region.

Optionally, a plurality of test units are provided in at least one side frame region of the non-display device area.

Optionally, the plurality of test units are disposed in a frame region close to a chip side of the display device area.

Optionally, the non-display device area comprises at least two magnetic force areas, and the test unit is located between the two magnetic force areas,
wherein an orthographic projection of the magnetic force area on a base does not overlap with an orthographic projection of the test unit on the base, and the magnetic force area is configured to adsorb a metal mask plate.

The present disclosure further discloses a mask plate, adapted to the display substrate above, the mask plate comprising:
a first area corresponding to a display device area on the display substrate; and
a second area corresponding to a non-display device area on the display substrate and comprising at least one sub-area, wherein the sub-area is arranged with an aperture corresponding to at least one of the measurement areas.

The present disclosure further discloses an evaporation system, comprising: a plurality of mask plates, and the display substrate above,
wherein the mask plate comprises a first pattern corresponding to a display device area and a second pattern corresponding to a non-display device area, and the second pattern corresponds to at least one measurement area located in the non-display device area.

Optionally, different mask plates have the same second pattern to jointly correspond to a plurality of measurement areas in the non-display device area; or different mask plates have different second patterns to be used separately for evaporating film layers corresponding to different measurement areas of the non-display device area.

According to the display substrate of the present disclosure, the display substrate includes the display device area, and the non-display device area adjacent to the display device area. The display device area is provided with the light emitting device layer, and at least one test unit is distributed in a planar direction of the non-display device area. Each test unit includes a plurality of measurement areas provided at intervals in the planar direction. The number of measurement areas in the test unit is not less than the number of film layers of the light emitting device layer, and each measurement area in the same test unit is configured to test at least one layer located in the light emitting device layer.

The display substrate of the present disclosure includes at least one test unit, a plurality of measurement areas are distributed in the test unit, and different measurement areas may correspond to at least one different film layer in the light emitting device layer. Therefore, when the light emitting device layer is formed layer by layer, a corresponding film layer may be formed on the corresponding measurement area so that the thickness of each film layer in the light emitting device layer may be determined based on the thickness of the film layer of the measurement area, and thus a thickness test of the light emitting device layer may be directly performed in the non-display device area of the display substrate.

In addition, the number of measurement areas distributed in the test unit is not less than the number of film layers in the light emitting device layer, which may realize a redundant design of the film layer thickness test. Thus, the production and testing of each film layer of the light emitting device layer may be fully satisfied, and a single substrate may be compatible with the film layer test of multiple types of light emitting device layers. In practice, a set of substrates may be produced to satisfy the preparation of different types of light emitting device layers, thereby reducing the production cost.

The above description is merely an overview of the technical solution disclosed in this document. To gain a clearer understanding of the technical means of this disclosure and to implement it according to the content of the specification, and to make the aforementioned and other purposes, features, and advantages of this disclosure more apparent and comprehensible, specific embodiments of this disclosure are provided below.

### BRIEF DESCRIPTION OF THE DRAWINGS

The above description is merely an overview of the technical solution disclosed in the disclosure. To gain a clearer understanding of the technical solutions of this disclosure, one can implement it according to the content of the specification. Furthermore, to make the aforementioned and other objectives, features, and advantages of this disclosure more apparent and comprehensible, specific embodiments of this disclosure are provided below.

FIG. 1a shows a schematic cross-sectional structure of an electroluminescent unit according to the present disclosure;

FIG. 1b shows a schematic cross-sectional structure of a tandem electroluminescent unit according to the present disclosure;

FIG. 2 shows a schematic top plan of a display substrate according to the present disclosure;

FIG. 3 shows a schematic top plan of a test unit according to the present disclosure;

FIG. 4a shows a schematic cross-sectional structure of a substrate according to the present disclosure;

FIG. 4b shows a schematic cross-sectional structure after forming a light emitting device on a substrate according to the present disclosure;

FIG. 5a shows a schematic plan layout of a test unit in a non-display device area;

FIG. 5b shows another schematic plan layout of a test unit in a non-display device area;

FIG. 5c shows another schematic plan layout of a test unit in a non-display device area;

FIG. 5d shows yet another schematic plan layout of a test unit in a non-display device area;

FIG. 5e shows still another schematic plan layout of a test unit in a non-display device area;

FIG. 6 shows a schematic distribution of evaporated film layers in measurement areas according to the present disclosure;

FIG. 7 shows a schematic top plan of a display substrate as shown in FIG. 5d;

FIG. 8 shows a schematic top plan of a mask plate;

FIG. 9 shows a schematic cross-sectional structure of a mask plate aligned with a base;

FIG. 10a shows a schematic alignment between a mask plate and a display substrate;

FIG. 10b shows another schematic alignment between a mask plate and a display substrate;

FIG. 11 shows a schematic top plan of a mask plate corresponding to a substrate shown in FIG. 5d;

FIG. 12 schematically shows the formation of the display substrate shown in FIG. 2; and

FIG. 13 schematically shows a flowchart of the steps of a method for testing the film thickness.

### REFERENCE NUMERALS

100—substrate, 200—display device area, 300—non-display device area, 301—test unit, 310—measurement area, 101—base, 102—gate insulation layer, 103—capacitor insulation layer, 104—interlayer dielectric layer, 105—passivation layer, 106—flat layer, 107—first electrode layer, 108—pixel definition layer, 109—organic light emitting layer, 110—second electrode layer, 1081—second opening, 1082—first opening, 1083—film layer A, 1084—film layer B, 400—first area, 500—second area, 501—sub-area, 5011—aperture, 5012—colored line, and 600—mask plate edge.

### DETAILED DESCRIPTION

To make the purposes, technical solutions, and advantages of this embodiment more clear, the following will combine the figures in this embodiment to provide a clear and complete description of the technical solution in this embodiment. Obviously, the described embodiments are only a part of the embodiments disclosed, not all of them. Based on the embodiments disclosed in the disclosure, all other embodiments obtained by a skilled person in the art without creative labor are within the scope of protection of this disclosure.

In the related art, in a process for preparing a display panel, required film layers are generally formed on a substrate layer by layer. Taking an OLED display panel as an example, if an evaporation process is adopted to form film layers, the film layers are evaporated on the substrate layer by layer. During the evaporation, a fine metal mask (FMM) is generally used. A plurality of apertures are arranged on the FMM, and one aperture corresponds to one sub-pixel of a display area, so as to form a masking cap with a pattern on the film layer. During the evaporation, a film layer material passes through the aperture on the FMM and is deposited on the film layer below the aperture, thereby forming a required light emitting layer.

In practice, it is required to detect whether the thickness of the film layer formed in a display device area meets the standard. Generally, a test region is added outside a display area (AA area) of the substrate. When a film layer is formed, a hole for the test region is arranged on the metal mask plate, and a film layer is formed in the test region simultaneously so that when a film layer is formed, a film is also formed at different positions in the test region. For example, for an OLED device, an electroluminescent unit is included. Referring to FIG. 1a, it shows a schematic cross-sectional structure of a light emitting device layer. As shown in FIG. 1a, an electroluminescent unit is provided between an anode and a cathode. The electroluminescent unit includes: a hole injection layer HIL located on the anode, a hole transport layer HTL located at a side of the hole injection layer facing away from the anode, an emissive layer EML located at a side of the hole transport layer HTL facing away from the HIL, an electron transport layer ETL located at a side of the emissive layer EML facing away from the HTL, and an electron injection layer EIL located at a side of the electron transport layer ETL facing away from the emissive layer.

The electroluminescent unit has seven film layers. Thus, seven film layers are distributed at seven positions on the test region. The thickness of each film layer in the display area may be known by testing the thicknesses of the seven film layers.

With the development of OLED display devices, the application of OLED screens in tablet, NB, vehicle-mounted, and other fields is gradually increasing, and high requirements are put forward for the service life of medium and large-sized screens. Thus, the film layer structure of a single electroluminescent unit commonly used in mobile phones and wearable products cannot meet the requirements, and a tandem double film layer structure is required to improve the service life. A tandem OLED display device includes two layers of electroluminescent units and generally has 15 film layers.

Therefore, as the demand for OLED display devices increases and diversifies, it is necessary to consider the production of a more compatible set of substrates to be compatible with the production and testing of OLED display devices with different film layer requirements, so as to reduce the production cost.

In view of the above, the present application provides a base that may be compatible with the production and testing of OLED display devices having different numbers of film layers. The base includes a display device area and a non-display device area. The display device area is configured to provide a light emitting device layer, and the non-display device area is configured to measure the light emitting device layer. Specifically, the non-display device area of the base may be redundantly designed with measurement areas, i.e., the number of measurement areas may be designed to be at least equal to the number of film layers of the light emitting device layer with the larger number of film layers in the two light emitting device layers, so as to be compatible with the light emitting device layers with different numbers of film layers, for example, at least compatible with the present tandem OLED light emitting device layer and the OLED light emitting device layer with a single organic electroluminescent unit.

In order to fully embody the improvement of the present application, taking a display substrate as an example, the improvement of the present application is described. The display substrate is a substrate formed with a light emitting device layer in a display device area of a base. After forming the light emitting device layer, a part or all of measurement areas in a non-display device area has been evaporated with film layers.

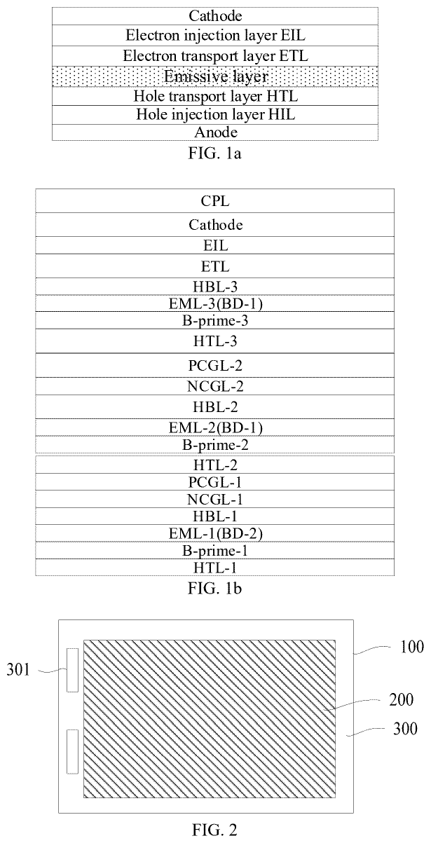

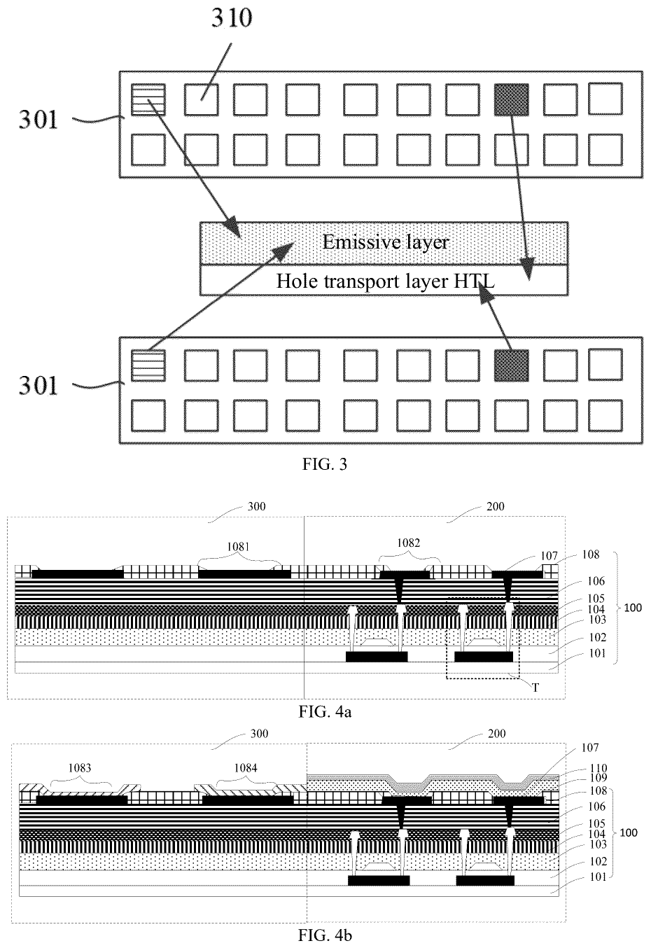

Referring to FIGS. 2 and 3, FIG. 2 shows a schematic top plan of a display substrate of the present application, and FIG. 3 shows a schematic top plan of a test unit of the present application. Referring to FIGS. 2 and 3, the display substrate of the present application is described.

As shown in FIGS. 2 and 3, the display substrate of the present application includes: a display device area 200, and a non-display device area 300 adjacent to the display device area 200; wherein
a light emitting device layer is located in the display device area 200;
at least one test unit 301 is located in the non-display device area 300 and distributed in a planar direction of the display substrate,
wherein the test unit 301 includes a plurality of measurement areas 310 provided at intervals in the planar direction.

The number of measurement areas 310 in the test unit 301 is not less than the number of film layers of the light emitting device layer, and each measurement area 310 in one test unit 301 is configured to test at least one layer located in the light emitting device layer.

The display substrate may refer to: a substrate on which the light emitting device layer has been formed in the display device area, and meanwhile, film layers of the measurement areas have been formed in all or a part of the measurement areas of the non-display device area while forming the film layers of the light emitting device layer. In practice, the non-display device area 300 may be cut to measure the thicknesses of the film layers formed in the measurement areas 310 in the non-display device area 300, thereby achieving the purpose of measuring the thicknesses of the film layers in the light emitting device layer.

The shape of the measurement area may be rectangular, circular, triangular, diamond, etc., and is not limited in the present application.

In this embodiment, the display substrate may include a substrate, and the substrate may include a substrate 100. The substrate 100 may be arranged with a pixel driving circuit to drive a pixel to emit light. In one case, the substrate may also be referred to as an array substrate and is configured to provide a power supply drive for the light emitting device layer so as to give the light emitting device layer an electrical drive required to emit light. Specifically, reference may be made to the schematic diagrams of the substrate structure shown in FIGS. 4a and 4b.

As stated in FIGS. 4a and 4b, the substrate 100 includes a plurality of data lines and a plurality of scanning lines, and the plurality of data lines and the plurality of scanning lines are interleaved to obtain a plurality of pixel regions. Each pixel region is provided with a pixel driving circuit. The pixel driving circuit includes a thin film transistor T. A gate electrode of the thin film transistor may be connected to the scanning line, a drain electrode of the thin film transistor may be connected to the data line, and a source electrode of the thin film transistor may be connected to the scanning line, so as to apply a driving voltage of the data line to a cathode or an anode of the electroluminescent unit under the scanning of the scanning line. As shown in FIG. 4a, the driving voltage is applied to a first electrode layer 107 so that an organic light emitting layer 109 located between the cathode and the anode emits light. The light emitting device layer in the display device area 200 is configured to display, and the non-display device area 300 may completely or partially enclose the display device area. FIG. 2 shows a case where the display device area is completely enclosed.

The non-display device area 300 is mainly configured to test devices of the display device area 200, including: testing the thickness of the film layer in the light emitting device layer, and testing the electrical contact between the light emitting device layer and the array substrate, for example, testing the performance of a transistor arranged in the array substrate.

The test unit is mainly configured to test the thickness of the film layer between the anode and the cathode in the light emitting device layer. There may be one or more, preferably a plurality of, test units. Specifically, the number of test units may be determined according to the size of the non-display device area. In the case where the size of the non-display device area is relatively large, the number of test units may be relatively large, and in the case where the size of the non-display device area is relatively small, the number of test units may be relatively small.

The plurality of test units may be provided at intervals in the non-display device area. That is, orthographic projections of the plurality of test units on the base do not overlap each other. Each test unit includes a plurality of measurement areas provided at intervals, and layers of the measurement areas may be formed when forming the layers between the anode and the cathode. Specifically, for the measurement area, the number of measurement areas in each test unit may be not less than the number of film layers in the light emitting device layer. According to actual situations, the number of measurement areas may be greater than the number of film layers between the cathode and the anode in the light emitting device layer, or at least equal to the number of film layers between the cathode and the anode in the light emitting device layer.

In some examples, for some test units, the number of measurement areas included therein is greater than the number of film layers between the cathode and the anode in the light emitting device layer, and the number of measurement areas included in the remaining test units is equal to the number of film layers between the cathode and the anode in the light emitting device layer. Thus, since the number of measurement areas included in the test unit is at least greater than the number of film layers of the light emitting device layer, the test unit may be compatible with light emitting device layers having a plurality of different film layers.

In still other examples, the number of measurement areas included in each test unit may be greater than the number of film layers between the cathode and the anode in the light emitting device layer. Of course, in this case, the number of measurement areas included in different test units may be the same or different.

In some examples, for each measurement area, it may be configured to test one layer located between the cathode and the anode of the light emitting device layer, or it may be configured to test two or more layers located between the cathode and the anode of the light emitting device layer. Thus, the total thickness of two layers in direct contact may be measured.

Since the number of measurement areas in the display substrate may be redundantly designed, at least one film layer between the anode and the cathode may also be formed on all or a part of the measurement areas. For the same test unit, a plurality of measurement areas may be provided with different film layers between the anode and the cathode. That is, a film layer formed on one measurement area and a film layer between the anode and the cathode in the light emitting device layer are the same film layer and are prepared in the same manufacturing process.

For embodiments with a plurality of test units, in different test units, it is possible to have measurement areas provided with the same film layers between the anode and the cathode. Illustratively, as shown in FIG. 2, two test units are included, and the two test units each include 20 measurement areas. As shown in FIG. 3, there are 15 measurement areas provided with film layers, and in the test unit 1 and the test unit 2, there are measurement areas provided with film layer A and film layer B. In practice, during the test, the thickness of a film layer in the light emitting device layer may be determined according to the average thickness of the film layers on a plurality of measurement areas on which the same film layer is evaporated.

According to the display substrate of the present disclosure, a plurality of measurement areas are distributed in the test unit, and each measurement area may correspond to at least one layer of the light emitting device layer preceding the cathode and the anode. Therefore, when the layers of the light emitting device layer are formed, a corresponding film layer may be formed on the corresponding measurement area so that the thickness of each film layer in the light emitting device layer may be determined based on the thickness of the film layer of the measurement area, and then a thickness test of the light emitting device layer may be directly performed on the non-display device area of the display substrate.

In addition, since the number of measurement areas of at least one test unit is greater than the number of film layers between the cathode and the anode in the light emitting device layer, a redundant design of the film layer thickness test is realized. Thus, the production and testing of each film layer of the light emitting device layer may be fully satisfied, and a single substrate may be compatible with the film layer test of multiple types of light emitting device layers. In practice, a set of substrates may be provided to satisfy the preparation of different types of light emitting device layers, thereby reducing the production cost. For example, the non-display device area may be compatible with the film layer test of the tandem OLED display device and the film layer test of the OLED display device with a single electroluminescent unit, or may be compatible with the film layer test of subsequent OLED display devices with more electroluminescent units.

In some optional examples, at least one electroluminescent unit is provided between the anode and the cathode of the light emitting device layer. For the OLED device with a single electroluminescent unit, the schematic structural diagram of the electroluminescent unit is shown in FIG. 1.

Of course, a plurality of electroluminescent units may also be included. In the case where a plurality of electroluminescent units are included, the plurality of electroluminescent units may be sequentially stacked, and a connection layer may be provided between each two electroluminescent units. The connection layer may transfer holes to one electroluminescent unit of the two electroluminescent units adjacent thereto and transfer charges to the other electroluminescent unit of the two electroluminescent units, thereby ensuring normal light emission of the emissive layer in each electroluminescent unit.

Specifically, reference can be made to FIG. 1b. FIG. 1b shows a film layer structure of the tandem OLED device, which includes a plurality of tandem electroluminescent units. As shown in FIG. 1b, taking a pixel emitting blue light as an example, a tandem structure of three electroluminescent units is shown, including, sequentially from close to the anode to far from the anode: HTI-1, B-prime-1, EML-1(BD-1), HBL-1, NCGL-1, PCGL-1, HTL-2, B-prime-2, EML-2(BD-1), HBL-2, NCGL-2, PCGL-2, HTL-3, B-prime-3, EML-3(BD-1), HBL-3, ETL, EIL, and CPL.

In the above-mentioned structure, the CPL is an optical coupling layer, the PCGL is a P-type charge generation layer, the NCGL is an N-type charge generation layer, and the B-prime is a blue light auxiliary emissive layer. It can be seen from the figure that two P-type charge generation layers and two N-type charge generation layers are included, and each emissive layer EML covers a blue light auxiliary emissive layer B-prime.

For the structure shown in FIG. 1b, the thickness of each layer may be as follows.

The CPL is 400-800 angstroms, the cathode is 120-200 angstroms, the EIL is 300-1,000 angstroms, the ETL is 250-350 angstroms, the HBL-3 is 50-200 angstroms, the EML-3 is 150-300 angstroms, the B-prime-3 is 50-100 angstroms, the HTL-3 is 50 -150 angstroms, the PCGL-2 is 50 -150 angstroms, the NCGL-2 is 100-250 angstroms, the HBL-2 is 50-200 angstroms, the EML-2 is 150-300 angstroms, the B-prime-2 is 50-100 angstroms, the HTL-2 is 50 -150 angstroms, the PCGL-1 is 50 -150 angstroms, the NCGL-1 is 100-250 angstroms, the HBL-1 is 50-200 angstroms, the EML-1 is 150-200 angstroms, the B-prime-1 is 50 -150 angstroms, and the HTL-1 is 50-200 angstroms.

In some optional examples, there is at least one test unit with the number of measurement areas greater than or equal to 20. Thus, the test unit may be compatible with at least three light emitting device layers, for example, compatible with a light emitting device layer with three organic electroluminescent units, a light emitting device layer with two organic electroluminescent units, and a light emitting device layer with one organic electroluminescent unit.

In an optional embodiment, referring to FIG. 4, a schematic cross-sectional structure of a base of the present application is shown. The display substrate includes at least: a substrate 100, a first electrode layer 107, and a pixel definition layer 108, wherein the first electrode layer 107 is provided close to the substrate 100, and the pixel definition layer 108 is located at a side of the first electrode layer 107 facing away from the substrate.

The pixel definition layer 108 located in the display device area 200 includes a plurality of first openings 1082 arranged at intervals, and orthographic projections of the first openings 1082 on the substrate 100 fall into an orthographic projection of the first electrode layer 107 on the substrate 100 The pixel definition layer 108 located in the non-display device area 300 includes a plurality of second openings 1081 arranged at intervals, and the second openings 1081 form the measurement areas.

The electroluminescent unit may be provided at a side of the pixel definition layer 108 facing away from the base and may be provided in the display device area as a whole. In addition, an orthographic projection of each film layer of the electroluminescent unit on the substrate 100 may cover the first electrode layer 107, i.e., covering the anode or the cathode as a whole. An organic light emitting film layer located within the first opening is considered as one pixel.

In the display device area, the first opening 1082 is mainly configured to define a pixel region, i.e., a sub-pixel constituting the display panel. In the non-display device area, the second opening 1081 forms a measurement area in which a film layer may be formed. In some examples, an orthographic projection of the second opening 1081 on the substrate may fall into the orthographic projection of the first electrode layer 107 on the substrate 100. Alternatively, in still other examples, the orthographic projection of the second opening 1081 on the substrate 100 may not overlap with the orthographic projection of the first electrode layer 107 on the substrate 100. It can be specifically set according to actual situations and is not particularly limited herein.

The first electrode layer 107 may be an anode or a cathode.

In the case where the orthographic projection of the second opening 1081 on the substrate falls into the orthographic projection of the first electrode layer 107 on the substrate 100, the second opening 1081 includes an anode or a cathode, for example, including an anode. Thus, when the emissive layer EML is formed at the second opening 1081, since the light emitting layer is in direct contact with the anode, a measurement area where the emissive layer EML is formed is caused to emit light when an electric current flows through the anode and an electric field is formed between the anode and the cathode. In this case, the light emitting efficiency of the emissive layer EML may also be tested while testing the thickness of the emissive layer EML.

Illustratively, the emissive layer EML includes a blue light emissive layer, a green light emissive layer, and a red light emissive layer. The selected material may be a host material emitting light of a corresponding color, or may be a mixture of a host material and a doping material (also referred to as a guest material). The doping material may be a light emitting material having a hole-transporting or electron-transporting function, for example, doped with a small amount of organic fluorescent or phosphorescent materials. In the measurement area where the emissive layer EML is formed, the film thickness, the service life, and the light emitting efficiency of the emissive layer EML may be tested. Thus, in the case where the second opening 1081 exposes the first electrode layer, when the measurement area thereof is formed with the emissive layer EML, tests on the service life and light emitting efficiency of the emissive layer EML may be performed, thereby giving the measurement area more measurement functions.

In one embodiment, a size of an orthographic projection of the second opening 1081 on the substrate is greater than a size of an orthographic projection of the first opening 1082 on the substrate. Thus, it is possible to make the area of the film layer formed in the measurement area larger when measuring the film thickness, so as to improve the accuracy of the film thickness test.

In yet another embodiment, a distance between the orthographic projections of two adjacent second openings 1081 on the substrate is greater than a distance between the orthographic projections of two adjacent first openings 1082 on the substrate. In this way, it is possible to facilitate cutting by the user when testing the film thickness.

In some optional examples, as shown in FIG. 4a, the substrate 100 may specifically include:
a base 101;
a gate insulation layer 102 located at a side of the base 101;
a capacitor insulation layer 103 located at a side of the gate insulation layer 102 facing away from the base 101;
an interlayer dielectric layer 104 located at a side of the capacitor insulation layer 103 facing away from the base 101;
a passivation layer 105 located at a side of the interlayer dielectric layer 104 facing away from the base 101; and
a flat layer 106 located at a side of the passivation layer 105 facing away from the base 101.

A first electrode layer 107 may be located at a side of the flat layer 106 facing away from the base 101.

The bottom of the second opening 1081 may directly contact the first electrode layer 107.

In some examples, as shown in FIG. 4a, a cross-sectional structure of the substrate in the display device area and the non-display device area is provided. It can be seen that in the case where the orthographic projection of the second opening 1081 on the substrate may not overlap with the orthographic projection of the first electrode layer 107 on the substrate 100, a bottom surface of the second opening 1081 may be the flat layer 106. That is, the second opening 1081 is open above the flat layer 106, and a film layer may be evaporated on the flat layer 106 during evaporating. In this case, the measurement area may be configured to measure the thickness of the film layer.

In this embodiment, the gate insulation layer 102 is configured to insulate the gate, the capacitor insulation layer is configured to further block the attack of substances such as water and oxygen on the basis of the gate insulation layer, and the passivation layer may transform a metal surface of the first electrode layer 107 into a state that is not easily oxidized, thereby delaying the corrosion rate of the first electrode layer 107. The interlayer dielectric layer 104 serves as an electrically insulating layer between different metal layers in the device, acting as an isolating film between two layers of conductive metal or adjacent metal lines.

FIG. 4a shows only the cross-sectional structure at the non-display device area 300. The display device area 200 forms the device structure of the OLED with the formation of the film layers lay by layer. The cross section of the device structure of the OLED may refer to the structure in the related art.

After forming the organic light emitting layer 109 between the first electrode layer and the second electrode layer on the substrate 100, the structure of the non-display device area and the structure of the display device area are obtained. As shown in FIG. 4b, in the display device area 200, the organic light emitting layer 109 is provided at the side of the first electrode layer 107 facing away from the substrate, and a second electrode layer 110 is provided at a side of the organic light emitting layer 109 facing away from the substrate. The first electrode layer 109 is an anode, and the second electrode layer 110 is a cathode. Of course, in other devices, the first electrode layer may also be a cathode, and the second electrode layer may also be an anode.

In the non-display device area 300, a film layer is provided at the side of the first electrode layer 107 facing away from the substrate, i.e., the film layer is formed in the second opening 1081. FIG. 4b illustratively shows a schematic diagram of film layers formed on two second openings 1081 (measurement areas). A film layer A1083 and a film layer B1084 are included. The two film layers may be two different film layers in the organic light emitting layer 109, or the same two film layers.

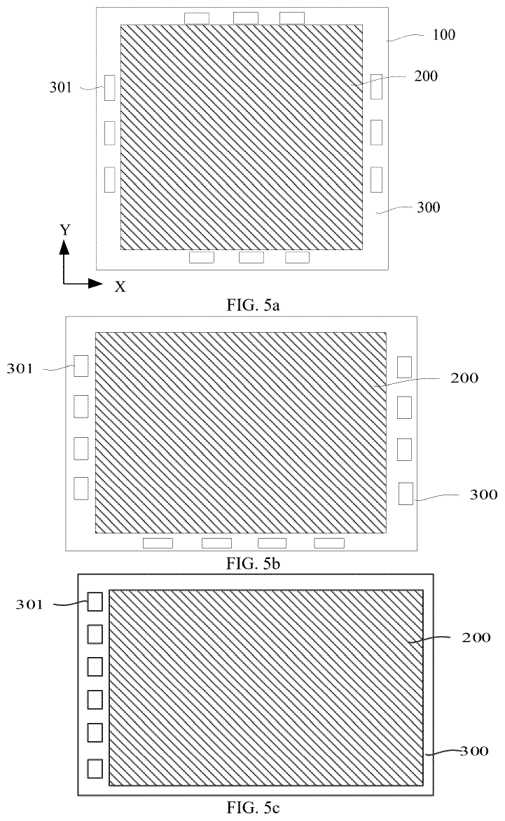

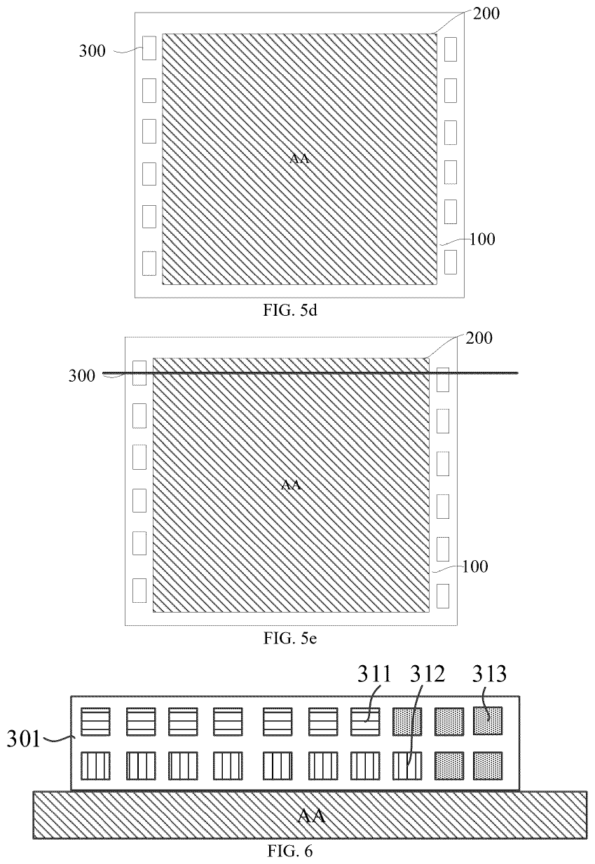

In some embodiments, the first opening 1082 may also be referred to as a pixel opening. Generally, a plurality of sub-pixels are arranged in an array along a planar direction of the substrate. The plurality of sub-pixels are arranged in a plurality of rows and a plurality of columns. A row direction may be a length direction of the planar direction, such as an X direction shown in FIG. 5a, and the column direction may be a width direction of the planar direction, such as a Y direction shown in FIG. 5 a. Specifically, the pixel opening may have a size in the row direction of 27-35 micrometers and a size in the column direction of 26-36 micrometers. In one example, since pixels emitting blue, green, and red light are included, pixels emitting light of different colors may have slightly different sizes in the row direction. Specifically, the interface may be set differently according to the requirements of the display panel for the color brightness.

In some embodiments, the size of the second opening 1081 in the planar direction may be greater than the size of the first opening 1082 in the planar direction, which may specifically refer to that: the size of the second opening 1081 in the row direction is greater than the size of the first opening 1082 in the row direction. For example, the size of the second opening 1081 in the row direction may be 40-55 micrometers. Of course, a larger size may be provided according to actual needs. Alternatively, the size of the second opening 1081 in the column direction is greater than the size of the first opening 1082 in the column direction.

Alternatively, the size of the second opening 1081 in both the row direction and the column direction is greater than the size of the first opening 1082 in both the row direction and the column direction.

Of course, in some embodiments, when the top view shape of the second opening 1081 in the planar direction is a circle or other shape different from a rectangle, a first area of the orthographic projection of the second opening 1081 on the substrate 100 may be greater than a second area of the orthographic projection of the first opening 1082 on the substrate 100. Specifically, a ratio of the first area to the second area is greater than or equal to 1.5.

Since the second opening 1081 forms a measurement area, after a film layer between the anode and the cathode is formed, at least one measurement area is provided with an emissive film layer in the light emitting device layer. The display device area includes a plurality of sub-pixels, wherein a size of an orthographic projection of the emissive film layer on the substrate is greater than a size of an orthographic projection of the sub-pixel on the substrate.

As described above, the emissive film layer includes an emissive layer and an auxiliary emissive layer. The emissive film layer includes a green light-emitting film layer, a blue light-emitting film layer, and a red light-emitting film layer. Generally, when forming the emissive film layer, the FMM is adopted, and an aperture at the beginning of the FMM corresponds to a sub-pixel. In this way, when forming the emissive layer of each light emitting color, an emissive film layer is correspondingly formed in a measurement area. Thus, in the test unit, there are at least three measurement areas formed with a green light-emitting film layer, a red light-emitting film layer, and a blue light-emitting film layer, respectively.

In some examples, the size of the orthographic projection of the emissive film layer on the substrate is greater than the size of the orthographic projection of the sub-pixel on the substrate, which may refer to that: the area of the orthographic projection of the emissive film layer on the substrate is greater than the area of the orthographic projection of the sub-pixel on the substrate, or the size of the emissive film layer in the length direction of the substrate is greater than the size of the sub-pixel in the length direction of the substrate, or the size of the emissive film layer in the width direction of the substrate is larger than the size of the sub-pixel in the width direction of the substrate.

Alternatively, the size of the emissive film layer in the width direction of the substrate is greater than the size of the sub-pixel in the width direction of the substrate, and the size of the emissive film layer in the length direction of the substrate is greater than the size of the sub-pixel in the length direction of the substrate.

In some embodiments, a spacing distance between the first openings 1082 may be determined according to the resolution of the display panel. In a specific example, the spacing distance between two adjacent first openings 1082 may be 0.15 mm-0.4 mm. However, a spacing distance between the second openings 1081 may be greater than the spacing distance between the first openings 1082, and for example, may be set to 0.5 mm.

In some embodiments, the size of the second opening 1081 in a normal direction of the plane of the display substrate may be at least greater than the size of the thickest film layer in the light emitting device layer, such as may be 200 nm.

Next, the layout of the test unit in the non-display device area 300 will be described.

In some embodiments, at least one test unit 301 is arranged in the non-display device area 300 at equal intervals.

The non-display device area may completely or partially enclose the display device area. A plurality of test units 301 being arranged at equal intervals may refer to that: the plurality of test units are distributed in at least one side frame of the non-display device area 300 and may be arranged at equal intervals in each side frame, specifically, arranged in an array. Alternatively, depending on the shape of the substrate, the non-display device area 300 may be a circular frame, in which case the plurality of test units are distributed in a partial region of the non-display device area 300 with the same spacing distance between every two adjacent test units 301. For example, the plurality of test units are arranged at equal intervals in a partial arc-shaped frame of the circular frame.

Referring to FIGS. 5a-5d, four schematic plan layouts of test units in the non-display device area are shown. In FIGS. 5a-5d, the non-display device area encloses the display device area and has a rectangular shape.

Specifically, a plurality of test units are provided in at least one side frame region of the non-display device area.

As shown in FIG. 5 a, illustratively, 12 test units may be included. The 12 test units may be distributed in four frames of the non-display device area 300, and each frame is uniformly distributed with 3 test units. In this distribution mode, the film thickness of each film layer in the light emitting device layer may be tested in each region in comparison with the other three distribution modes, thereby improving the uniformity and comprehensiveness of the film thickness test.

As shown in FIG. 5b, the 12 test units may be distributed in three frames of the non-display device area 300, and each frame is uniformly distributed with 4 test units. In this distribution mode, the film thickness of each film layer between the anode and the cathode in the light emitting device layer may still be tested in different display regions.

As shown in FIG. 5c, in some cases, the test units may also be uniformly distributed in only one frame of the non-display device area 300, such as uniformly distributing 6 test units on one long frame of the non-display device area 300. In this distribution mode, the film thickness of each film layer in the light emitting device layer may be tested at different positions in one side region.

Specifically, in the case where a plurality of test units are distributed in one frame region of the non-display device area 300, the frame region may be a frame region close to a chip side of the display device area.

Of course, FIGS. 5a-5c are merely exemplary illustrations and do not represent specific limitations on the number and distribution mode of test units.

In practice, in the non-display device area 300, in addition to the test units 301, an electrical property test unit may also be included. The electrical property test unit may include a test transistor, a plurality of test leads, and a plurality of test pins. The test transistor has the same structure as at least one transistor in the pixel driving circuit in the substrate 100, the plurality of test pins are connected to the test transistor through the plurality of test leads, and the actual characteristics of the transistor in the display device area may be accurately reflected through the electrical property test unit. The specific structure of the electrical property test unit and the test process may refer to the related art and will not be repeated herein.

Since the non-display device area 300 generally further includes the electrical property test unit, in some optical examples, the test units 301 are distributed in two opposite frame regions of the non-display device area 300 surrounding the display device area 200 in the case where the non-display device area 300 encloses the display device area 200.

Specifically, in the case where the non-display device area 300 completely encloses the display device area 200, the non-display device area 300 may include a first frame region and a second frame region oppositely provided in a first direction, and a plurality of test units are provided in the first frame region and/or the second frame region.

The first direction may be a long side direction or a short side direction of the substrate 100, or the first direction may be a direction of a side where the chip on the substrate 100 is located. The plurality of test units 301 may be provided in the first frame region, the second frame region, or the first frame region and the second frame region. The first frame region and the second frame region are two regions opposite in the first direction, such as two regions opposite in the short side direction or two regions opposite in the long side direction.

As shown in FIGS. 5d, 6 test units may be uniformly distributed in each of the two opposite frames of the non-display device area 300.

The arrangement of the measurement areas of each test unit is described.

In one example, as shown in FIG. 5d, a plurality of test units may be symmetrically provided in the first frame region and the second frame region. That is, the number and positions of the plurality of test units on the first frame region are consistent with the number and positions of the plurality of test units on the second frame region.

In another example, in the case where the plurality of test units are provided in the first frame region and the second frame region, a straight line parallel to the first direction passes through one test unit located in the first frame region or passes through one test unit located in the second frame region. That is, the plurality of test units may be asymmetrically provided in the first frame region and the second frame region. For example, at least one of the number and positions of the plurality of test units on the first frame region is different from the number and positions of the plurality of test units on the second frame region.

Referring to FIG. 5e, in still another example, in the case where the plurality of test units are provided in the first frame region and the second frame region, a straight line parallel to the first direction simultaneously passes through one test unit located in the first frame region and one test unit located in the second frame region. That is, the plurality of test units may be symmetrically or asymmetrically provided in the first frame region and the second frame region. For example, the number of the plurality of test units in the first frame region is consistent with the number of the plurality of test units in the second frame region, but the positions thereof may be consistent or inconsistent, i.e., the positions of two test units passed by the same straight line may be different on the respective frame regions.

In some optional examples, as shown in FIG. 3, a plurality of measurement areas may be arranged in an array in the planar direction. Specifically, the plurality of measurement areas may be sequentially arranged in one row according to the size of the non-display device area, or may be arranged in a plurality of rows. In FIG. 3, the plurality of measurement areas are arranged in two rows.

In the case where the plurality of measurement areas are arranged in an array, in some optional examples, the plurality of measurement areas include first measurement areas 311 provided with first type film layers and second measurement areas 312 provided with second type film layers. The first measurement area 311 is located at a side of the second measurement area 312 facing away from the display device area 200.

Specifically, the first type film layer and the second type film layer may be different types of film layers. In this way, the measurement area for testing the same type of film layer is provided away from the display device area 200, and the measurement area for testing the other type of film layer is provided close to the display device area 200 so that when forming each layer of the light emitting device layer, it is possible to facilitate plating of the non-display device area by a worker and facilitate subsequent tests by a tester. That is, during the test, the test positions where the first type film layer and the second type film layer are located may be easily distinguished, thereby improving the test efficiency.

In some optional examples, the first type film layer is a common film layer, such as a carrier-transporting film layer, and the second type film layer is an emissive film layer. In this example, the carrier-transporting film layer is typically made of a metal material so that depositing a film layer of a metal material on a side away from the display device area 200 may avoid crosstalk of the metal material to the light emitting device layer of the display device area.

The emissive layer may include a blue light-emitting electroluminescent material, a green light-emitting electroluminescent material, and a red light-emitting electroluminescent material. When forming the emissive layer in the light emitting device, different light emitting electroluminescent materials are generally formed at the positions of different first openings. For example, in three adjacent first openings, a blue light-emitting layer, a green light-emitting layer, and a red light-emitting layer are formed, respectively.

Thus, in the measuring region 310, a measurement area provided with a blue-light emitting film layer, a measurement area provided with a green light-emitting film layer, and a measurement area provided with a red light-emitting film layer are also included.

In some optional examples, for the display device area 200, an orthographic projection of the first type film layer on the substrate 100 may completely cover the display device area 200, and an orthographic projection of the second type film layer on the substrate 100 partially covers the display device area 200.

Taking the OLED light emitting device layer as an example, the first type film layer may also be a cathode film layer. In some cases, an emissive layer may also be included. The second type film layer may also be an electron transport layer, an electron injection layer, a hole transport layer, a hole injection layer, etc.

In some optional examples, the first type film layer includes at least one of the electron injection layer, electron transport layer, hole injection layer, hole transport layer, hole barrier layer, electron barrier layer, and second electrode layer, and the second type film layer may include an emissive layer. The materials of the electron injection layer, electron transport layer, hole injection layer, hole transport layer, hole barrier layer, electron barrier layer, charge generation layer, second electrode layer, and light extraction layer are all metal materials or are doped with metal materials. In this way, when the first type film layer is provided at a side facing away from the display device area 200, electrical crosstalk caused by the first type film layer to the display device area 200 may be avoided. Since this type of film layer is generally made as a whole layer, its orthographic projection on the display substrate may completely cover the display device area 200.

The light extraction layer may reduce an incident angle of an incident light ray of the sub-pixel to avoid generating total reflection as much as possible so that the light rays generated by the sub-pixel may be completely transmitted, thereby improving the light extraction rate, improving the light emitting efficiency, and reducing the power consumption.

The second electrode layer may be a metal connection layer between two electroluminescent units.

The second type film layer may include an emissive layer and an auxiliary emissive layer. The auxiliary emissive layer is located between the emissive layer and the first electrode layer. In sub-pixels emitting different colors, the thicknesses of the auxiliary emissive layers may be different. The material of the auxiliary emissive layer may be an arylamine derivative, which may have a function as the hole transport layer and may be in direct contact with the emissive layer. As shown in FIG. 1b, the auxiliary emissive layer may be a B prime layer. The material of the emissive layer may vary according to the color of light to be emitted.

Since the emissive layer needs to emit light of red, blue, green, or more colors, it is necessary to form light of different colors separately in pixel opening areas so that the emissive layer of each color covers a part of the display device area. In addition, since the emissive layer is generally made of an electroluminescent material, such as an organic electroluminescent material, it may be provided close to the display device area 200. According to the above-mentioned mode, the common film layer and the film layer requiring FMM mask manufacturing may be separately measured at different measurement areas, thereby facilitating user testing.

In some optional examples, the number of measurement areas in at least one test unit is greater than the number of film layers of the light emitting device layer. That is, there is at least one test unit including a greater number of measurement areas than the number of film layers of the light emitting device layer. In this case, the plurality of measurement areas include a plurality of third measurement areas 313. That is, when forming the light emitting device layer, a part of the measurement areas may be formed with the film layer between the anode and the cathode, and the rest of the measurement areas may not be formed with the film layer between the anode and the cathode.

Specifically, the third measurement area 313 is provided with a protective layer, and in the plurality of third measurement areas, the number of third measurement areas provided at the same side as the first measurement area is greater than the number of third measurement areas provided at the same side as the second measurement area.

The first measurement area 312 is provided with a common film layer, such as the electron injection layer, electron transport layer, hole injection layer, hole transport layer, hole barrier layer, electron barrier layer, charge generation layer, second electrode layer, and light extraction layer, and the second measurement area is provided with an emissive layer and an auxiliary emissive layer. For the tandem OLED device, the more tandem light emitting device layers, the more the number of common film layers increases. The increased number of the emissive layers is generally less than the increased number of the common film layers. Thus, in some embodiments, a plurality of third measurement areas may be provided at the same side as the first measurement area, and a plurality of third measurement areas may also be provided at the same side as the second measurement area. In addition, the number of third measurement areas provided at the same side as the first measurement area is larger than the number of third measurement areas provided at the same side as the second measurement area. Thus, a redundant film thickness measurement design may be provided for a plurality of tandem OLED devices.

A protective layer is provided in the third measurement area and configured when a test unit of the non-display device area has a redundant design to prevent a film layer in the light emitting device layer from being formed into the third measurement area when forming the light emitting device layer (i.e., the number of measurement areas of one test unit is greater than the number of film layers in the light emitting device layer). Specifically, the protective layer may be a protective film removable from the third measurement area, such as a transparent film bonded to the third measurement area.

In this case, each test unit of the display substrate may include a plurality of first measurement areas, a plurality of second measurement areas, and a plurality of third measurement areas. The plurality of first measurement areas are provided with an electron injection layer, electron transport layer, hole injection layer, hole transport layer, hole barrier layer, electron barrier layer, charge generation layer, second electrode layer, and light extraction layer. Different first measurement areas are provided with different ones of the above-mentioned common film layers. The plurality of second measurement areas are provided with emissive layers and auxiliary emissive layers with different light emitting colors. Of course, depending on the type of the display substrate, two green light-emitting film layers, two red light-emitting film layers, two blue light-emitting film layers, and two white light-emitting film layers may be included. The third measurement area is provided with a protective layer, which does not form any film layer in the light emitting device.

Of course, in the case where it is necessary to form a film layer in the light emitting device in the third measurement area, the protective layer may be removed, and then the above-mentioned film layer may be formed.

For each measurement unit, the first measurement areas and the second measurement areas may be arranged along the extension direction of the frame region according to the extension direction of the frame region of the non-display device area where the measurement unit is located. As shown in FIG. 5a, when the measurement units are located in the frame region in the X direction, the first measurement areas and the second measurement areas are arranged in two rows along the X direction, one row for the first measurement areas and another row for the second measurement areas. A plurality of third measurement areas are distributed in the row where the first measurement areas are located, and a plurality of third measurement areas are distributed in the row where the second measurement areas are located. In addition, the first measurement areas are close to the display device area.

Illustratively, as shown in FIG. 5a, when the measurement units are located in the frame region in the Y direction, the first measurement areas and the second measurement areas are arranged in two columns along the Y direction, one column for the first measurement areas and another column for the second measurement areas. A plurality of third measurement areas are distributed in the column where the first measurement areas are located, and a plurality of third measurement areas are distributed in the column where the second measurement areas are located. In addition, the first measurement areas are close to the display device area.

Referring to FIG. 6, a schematic diagram of film layers formed in the measurement area is shown. As shown in FIG. 6, the arrangement of the third measurement area 313, which is not formed with the film layer, may make the substrate compatible with a light emitting device layer having a greater number of film layers.

As shown in FIG. 6, in the case where a plurality of measurement area are arranged in an array, the third measurement area 313 may be in the same array as the first measurement area 311 or in the same array as the second measurement area 312. That is, the third measurement area 313 may be arranged in a row or a column with the first measurement area 311 or the second measurement area 312.

The number of third measurement areas 313 in the same row as the first measurement area 311 is greater than the number of third measurement areas 313 in the same row as the second measurement area 312. As shown in FIG. 6, the number of third measurement areas 313 in the same row as the first measurement area 311 is three, and the number of third measurement areas 313 in the same row as the second measurement area 312 is two. In this way, a sufficient number of measurement areas may be provided for the testing of the first type film layer in the light emitting device layer.

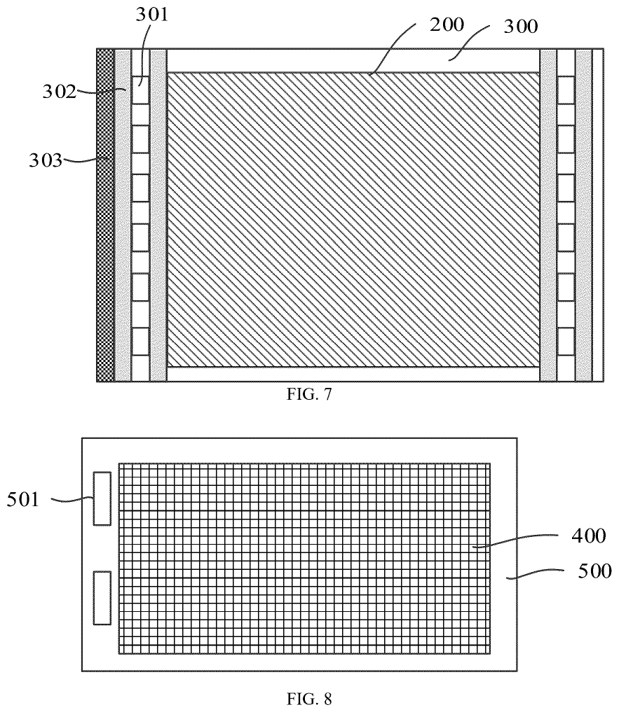

Referring to FIG. 7, a schematic top plan of a display substrate is shown. In some optional examples, the non-device display area 300 includes at least two magnetic force areas 302, and a test unit 301 is located between the two magnetic force areas 302.

An orthographic projection of the magnetic force area 302 on the substrate 100 does not overlap with an orthographic projection of the test unit 301 on the substrate 100.

In this optional example, the magnetic force area 302 is provided with a magnetic element to adsorb a metal mask plate. That is, when the metal mask plate is placed on the base, the magnetic force area 302 may adsorb the metal mask plate so that the mask plate may be more stably provided on the base to improve the accuracy of the later evaporation of the film layer.

In some optional examples, the non-device display area also includes a glass key area 303 located at the periphery of the magnetic force area 302 away from the display device area 200.

Based on the above-mentioned inventive concept, with the development of OLED devices, an OLED display device using the color on encapsulation (COE) technology also appears. The COE technology refers to forming a black material layer corresponding to an OLED sub-pixel on the surface of an OLED screen. The black material layer has a plurality of openings, and an orthographic projection of one opening on the base covers a first opening in the pixel definition layer. A color film layer corresponding to different color light emitting elements is provided in the opening (the color film layer and the black material layer are referred to as a COE layer for short). The black material layer can efficiently absorb all wavelengths of the ambient light. The color film layer can ensure that the display light ray reflected by the OLED material is transmitted, and can also effectively absorb light of other wavelengths in the ambient light which are different from the corresponding primary color. Therefore, it is unnecessary to provide a polaroid, thereby reducing the thickness of the display substrate.

In this type of OLED device, the film thickness of the color film layer and the film thickness of the black material layer are related to the transmission rate of light rays emitted from the OLED substrate and the absorption rate of ambient light. Therefore, it is required to test the respective film thicknesses of the black material layer and the color film layer, and at least one test unit of a plurality of test units may be configured to test the film thicknesses of the black material layer and the color film layer. Thus, when forming the COE layer, the black material layer and the color film layer may be formed together in the measurement area of the test unit. It is understood that in the case where the sub-pixels include three sub-pixels of RGB, the color film layer also includes three color film layers of RGB. Therefore, a red color film layer, a green color film layer, a blue color film layer, and a black material layer may be formed at a plurality of measurement areas. Thus, the film thickness of the COE layer may be determined by testing the film thickness of the measurement area. Therefore, it may be convenient for a tester to determine the relationship among the film thickness of the color film layer and the film thickness of the black material layer, the transmission rate of light rays emitted from the OLED substrate, and the absorption rate of ambient light so that a good COE layer may be designed.

Based on the same inventive concept, the present disclosure may also provide a mask plate. As described above, the mask plate is configured to provide a patterned masking cap for the formation of each film layer when forming the light emitting device layer so that the mask plate is adopted to evaporate a pattern on one film layer to form another film layer during the evaporation.

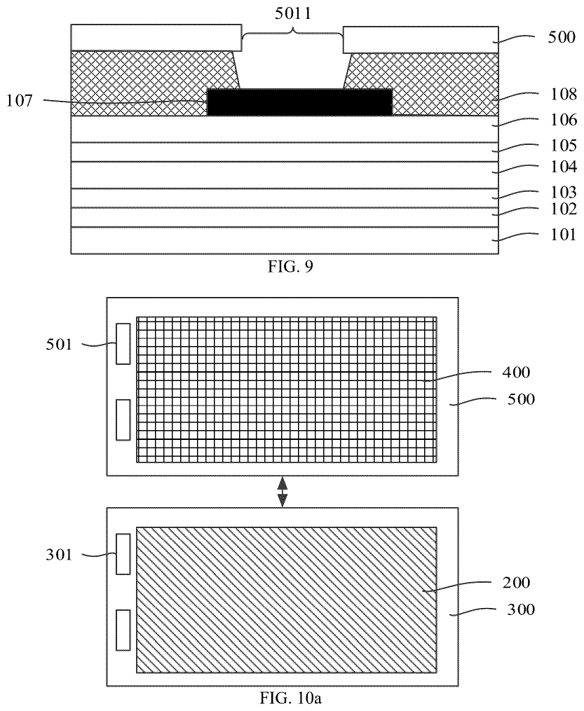

Specifically, referring to FIGS. 8 and 9, FIG. 8 shows a schematic top plan of a mask plate, and FIG. 9 shows a schematic cross-sectional structure of a mask plate aligned with a substrate on which a film layer is to be formed.

As shown in FIG. 8, the mask plate is adapted to a substrate 100 in the above-mentioned display substrate. The mask plate includes:
a first area 400 corresponding to the display device area 200; and
a second area 500 corresponding to the non-display device area 300 and including at least one sub-area 501, wherein the sub-area 501 is arranged with an aperture 5011 corresponding to one measurement area 310.

The mask plate may be a metal mask plate, or may be a mask plate of other materials.

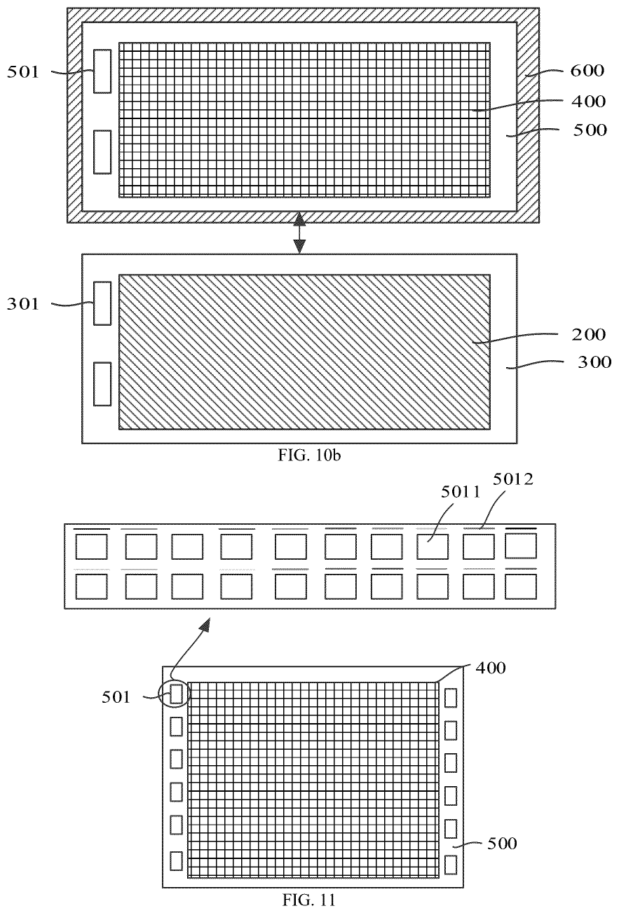

Referring to FIGS. 10a and 10b, schematic alignments between a mask plate and a substrate on which a film layer is to be formed are shown.

In some examples, as shown in FIG. 10a, the adaptation may refer to a size adaptation. For example, the mask plate has the same planar size as the substrate 100, for example, having rectangular shapes and circular shapes of the same size. In this case, the alignment precision may be ensured, thereby improving the accuracy of the film layer during evaporating.

Of course, in some cases, as shown in FIG. 10b, adaptation may also refer to that the mask size (including the first area 400 and the second area 500) of the mask plate is the same as the planar size of the substrate on which a film layer is to be formed, and the overall size of the mask plate may be slightly greater than the size of the base. That is, in practice, the mask plate has an edge 600 enclosing the second area so that when aligning the mask plate and the substrate on which a film layer is to be formed, the measurement area may be aligned with the substrate on which a film layer is to be formed, and the edge 600 may be located on the outside. In this case, manual holding of the mask plate may be facilitated to adjust the mask plate to be aligned with the substrate.

The planar size of the first area 400 may be the same as the size of the display device area 200 so that the orthographic projection of the first area 400 on the substrate 100 may coincide with the display device area 200 when the mask plate is aligned with the substrate.

The planar size of the second area 500 may also be the same as the size of the non-display device area 300 so that the orthographic projection of the second area 500 on the substrate may coincide with the non-display device area 300 when the mask plate is aligned with the substrate.

One sub-area 501 of the second area 500 corresponds to the test unit 301 on the substrate. That is, when the mask plate is aligned with the substrate, the orthographic projection of the sub-area 501 on the substrate 100 may coincide with the test unit 301 on the substrate 100, or the orthographic projection of the sub-area 501 on the substrate 100 falls at least into the test unit 301 on the base.

The number of sub-areas 501 may be the same as or different from the number of test units 301, and the number of apertures 5011 arranged by the sub-areas 501 may be less than the number of measurement areas 310 in the corresponding test unit 301, or may be equal to the number of measurement areas 310 in the corresponding test unit 301. In the case where the number of sub-areas 501 may be the same as the number of test units 301, and the number of apertures 5011 is the same as the number of measurement areas 310, the second areas of different mask plates may be the same, thereby simplifying the production process of the mask plates.

Specifically, in some examples, one sub-area 501 may be arranged with only one aperture 5011 so that for one mask plate, the film layer may start to form only by aligning the mask plate and the substrate on which a film layer is to be formed. When forming the film layer, a film layer is evaporated on only the measurement area 310 below the one aperture 5011, while the film layer is not evaporated on the other measurement areas 310, thus facilitating the evaporation of the film layer.

In still other examples, one sub-area 501 may be arranged with a plurality of apertures 5011, and the number of the plurality of apertures 5011 may be the same as the number of measurement areas 310. Thus, for a mask plate, the second areas of the mask plate may be formed in batches using the same process, simplifying the manufacturing process of the mask plate and improving the manufacturing efficiency of the mask plate. When the film layer of the light emitting device layer is evaporated, after the substrate 100 and the mask plate are aligned, only one corresponding aperture may be retained, and the other apertures may be covered to form the film layer.

Based on this, in some examples, in the case where the number of apertures 5011 of the sub-area 501 is the same as the number of measurement areas 310, the apertures 5011 on the mask plate may be marked. Different apertures 5011 use different marks, and the mark may be configured to identify which film layer in the light emitting device the aperture corresponds to. For example, the mark of aperture 5011 may identify that the aperture corresponds to the electron transport layer ETL film layer in the light emitting device. In this way, in the evaporation of the film layer, after the substrate and the mask plate are aligned, according to the mark of the aperture and the film layer corresponding to this mask plate, a corresponding aperture may be retained, while the other apertures are covered, and then the film layer evaporation or deposition process is performed.

The marks may be represented by letters, numbers, or lines of different colors, and are not particularly limited. Specifically, in some optional examples, the mark may be located in an edge region of the aperture. In order not to occupy too much space in the second area, the mark may be selected as a colored line which may be located at an edge of the aperture. For example, the mark may enclose the edge, coincide with the edge, cover a part of the edge, or cover the entire edge.

Referring to FIG. 11, a schematic top plan of a mask plate corresponding to the substrate shown in FIG. 5d is shown. As shown in FIG. 11, the second area of the mask plate includes 12 sub-areas 501, and the top plan structure of each sub-area 501 is as shown in the enlarged image in FIG. 11. The arrangement of the apertures 5011 of the sub-areas 501 is the same as the arrangement of the measurement areas 310 in the test units of FIG. 3, and there are 20 apertures in total. The edge of each aperture 5011 is marked with a colored line 5012, and different apertures 5011 correspond to different colors of the colored lines 5012.

When the substrate is aligned with the mask plate, an orthographic projection of the aperture 5011 arranged by the sub-area 501 on the substrate may coincide with the corresponding measurement area 310, or the orthographic projection of the aperture 5011 arranged by the sub-area 501 on the substrate 100 falls into the measurement area 310. That is, in the planar direction of the display substrate, the size of an opening area of the aperture 5011 is smaller than or equal to the size of the measurement area 310.

As shown in FIG. 9, the orthographic projection of the aperture 5011 arranged by the sub-area 501 on the substrate 100 falls into the measurement area 310.

In the case where the orthographic projection of the aperture 5011 arranged by the sub-area 501 on the substrate 100 falls into the measurement area 310, the shape of the opening area of the aperture 5011 may be the same as or different from the shape of the measurement area 310 in the planar direction of the display substrate. For example, the opening area of the aperture 5011 and the measurement area 310 are both circular or rectangular. Alternatively, the opening area of the aperture 5011 is circular, and the measurement area 310 is rectangular.

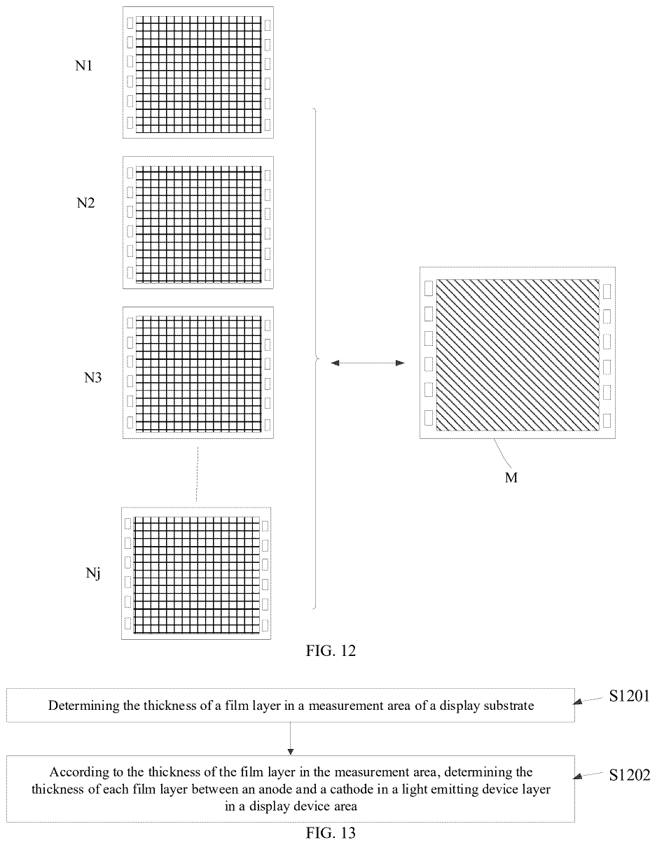

In practice, a substrate and a plurality of mask plates may be provided so that a light emitting device layer is formed on the substrate using the plurality of mask plates, thereby obtaining a display substrate. Referring to FIG. 12, the formation of the above-mentioned display substrate shown in FIG. 2 is shown. As shown in FIG. 12, a substrate M and a plurality of mask plates N1-Nj matched with the substrate M are included. Different mask plates correspond to the preparation of different film layers in a light emitting device layer. Specifically, the first area 400 of the mask plate is provided with a pattern required for preparing a corresponding film layer.

Illustratively, taking the display substrate being the structure with a single organic electroluminescent unit as an example, when the light emitting device layer includes 10 film layers, there are 10 mask plates, and different mask plates correspond to different film layers shown in FIG. 1. Illustratively, taking the display panel being a tandem OLED display panel as an example, when two organic electroluminescent units are included, 15 film layers are included, and there are 15 mask plates.

The pattern of the first area of each mask plate is adapted to the pattern of the film layer to which the mask plate corresponds, and the second area of each mask plate is shown with reference to the structure of the second area of the mask plate in the above-mentioned embodiment, which will not be repeated herein.

When forming a display substrate, after aligning the corresponding mask plate with the substrate according to the stacking sequence of the film layers in the light emitting device layer, the corresponding material is adopted to form a film layer on the base using an evaporation process or a deposition process. When forming the film layer, film layers are formed on both the display device area 200 and the corresponding measurement area of the non-display device area 300.

As described in the above-mentioned embodiment, when forming each film layer between the cathode and the anode in the light emitting device layer, in the second area 500 of the mask plate, one aperture 5011 in one sub-area 501 may be retained, while the other apertures 5011 are covered. In this case, each film layer of the light emitting device layer has only one measurement area formed with the film layer. Alternatively, only one aperture 5011 is retained for each sub-area 501, while the other apertures 5011 are covered. In this case, each film layer of the light emitting device layer has a plurality of measurement areas formed with the film layer, and the plurality of measurement areas may be located in different test units.

Illustratively, taking FIG. 1 as an example, assuming that it is currently required to form a hole transport layer HTL, a mask plate corresponding to the hole transport layer HTL is aligned with a substrate, and then evaporation (in practice, other processes can also be used) is performed above the mask plate using a hole transport material so that a hole transport material head is deposited on the substrate through the hollow on the mask plate, thereby forming the hole transport layer HTL in the display device area and forming a film layer in a measurement area of each test unit of the substrate. The hole transport material may be a material in the related art, such as poly(phenylenevinylene) (PPv), polythiophenes, polysilanes, triphenylmethanes, triarylamines, hydrazones, pyrazolines, oxazoles, carbazoles, and butadienes.

According to the above-mentioned process, all the film layers required in the light emitting device layer may be formed layer by layer, and there are corresponding film layers on the measurement areas of the substrate. Since the film layers in the light emitting device layer and the film layers on the corresponding measurement areas are generally formed under the same process, the thicknesses of the film layers in the light emitting device layer may be obtained by measuring the thicknesses of the film layers on the measurement area.

Based on the same inventive concept, a method for testing the film thickness is also provided. Referring to FIG. 13, a flowchart of the steps of the method for testing the film thickness is shown. As shown in FIG. 13, the method may specifically include the following steps:
S1201: determining the thickness of a film layer in a measurement area of a display substrate; and
S1202: according to the thickness of the film layer in the measurement area, determining the thickness of each film layer between an anode and a cathode in a light emitting device layer in a display device area.

Referring to FIG. 3, a film layer formed on a measurement area 310 is prepared at the same time as a film layer in the light emitting device layer so that a plurality of film layers may be stacked in the light emitting device layer and tiled in the non-display device area 300. Thus, each film layer is an independent film layer in the non-display device area 300. Therefore, the thickness of the film layer in the light emitting device layer may be obtained according to the thickness of the film layer in the measurement area.

The measurement mode of the thickness of the film layer may refer to the related art, for example, using a thickness gauge.

In the case where one film layer in the light emitting device layer has a film layer only in one measurement area, the thickness of the film layer in the measurement area may be taken as the thickness of the film layer in the light emitting device layer. In the case where one film layer in the light emitting device layer has film layers in a plurality of measurement areas, the average thickness of the film layers in the plurality of measurement areas may be taken as the thickness of the film layer in the light emitting device layer.

Of course, specifically, for the case where one film layer in the light emitting device layer has film layers in a plurality of measurement areas, the following two optional examples are provided for the measurement of the thickness of each film layer in the light emitting device.

Example 1: the thickness of a corresponding film layer in the light emitting device layer is determined based on the average thickness of a plurality of measurement areas provided with the same film layer.

Taking FIG. 5d as an example, one film layer in the light emitting device layer will have film layers in 12 measurement areas, and in practice, the average thickness of the film layers in the 12 measurement areas may be taken as the thickness of the film layer in the light emitting device layer.

According to this film thickness measurement mode, the measurement accuracy of the film layer in the light emitting device layer may be improved.

Example 2: the region thicknesses of the corresponding film layers in the light emitting device layer are determined in different regions based on the thicknesses of the plurality of measurement areas provided with the same film layer.

Taking FIG. 5d as an example, one film layer in the light emitting device layer will have a film layer (first film layer) in 12 measurement areas. The measurement areas at different positions may reflect the thickness of the corresponding film layer in the display device area in different regions. Thus, the thickness of each first film layer may be taken as the film layer thickness of the corresponding film layer in the display device area in this region.

According to this film thickness measurement mode, regional process differences in the preparation of each film layer in the light emitting device layer may be distinguished, thereby facilitating personnel to adjust the process parameters of the process, so that the formed film layer may be more uniform. Alternatively, for film layers with different thickness requirements in different regions, whether the film layer thicknesses in different regions meet the requirements may be measured according to the thickness of the measurement area at each position.

The above-mentioned mode in example 1 and the above-mentioned mode in example 2 may be combined to measure the average thickness of the film layers and the thicknesses of the film layers in different regions.

Based on the same inventive concept, an evaporation system is further disclosed. The evaporation system may include a plurality of mask plates, and the plurality of mask plates correspond to a plurality of layers in the above-mentioned display substrate, respectively.

The mask plate includes a first pattern corresponding to a display device area and a second pattern corresponding to a non-display device area, and the second pattern corresponds to at least one measurement area located in the non-display device area.

In one example, different mask plates have the same second pattern to jointly correspond to the measurement areas in the non-display device area; or different mask plates have different second patterns to be used separately for evaporating film layers corresponding to different measurement areas of the non-display device area.

For example, different mask plates having the same second pattern may refer to that: the number of a plurality of apertures 5011 arranged for the measurement areas on different mask plates may be the same as the number of measurement areas 310. Thus, for a mask plate, the second areas of the mask plate may be formed in batches using the same process, simplifying the manufacturing process of the mask plate and improving the manufacturing efficiency of the mask plate. When the film layer of the light emitting device layer is evaporated, after the substrate 100 and the mask plate are aligned, only one corresponding aperture may be retained, and the other apertures may be covered to form the film layer.

Of course, in some embodiments, the plurality of mask plates may also include a common mask plate and an FMM. The common mask plate may be adapted to a plurality of layers in the display device area simultaneously, i.e., layers with the same pattern distribution. For example, a plurality of layers in the electroluminescent unit have the same pattern so that a common mask plate may be used. However, the FMM is generally adapted to only one layer in the display device area, i.e., a plurality of FMMs are required to adapt to layers with different patterns.

The display substrate and the mask plate provided by the present disclosure have the following advantages.

1. Since a plurality of test units may be arranged at equal intervals in the non-display device area, and a plurality of measurement areas may also be arranged in an array, the arrangement scheme of the non-display device area is designed to be simple.

2. Since the number of measurement areas provided by the test unit is greater than the number of film layers in the light emitting device layer, a redundant design of the film layer thickness test is realized so that one base may be compatible with the film layer test of multiple types of light emitting device layers. In addition, a review scheme may be prepared in advance by adding measurement areas to provide a solution for increasing the number of film layers in the light-emitting device layer in the future.

3. Since the measurement areas of the first type film layer and the measurement areas of the second type film layer may be arranged in areas, possible crosstalk due to the proximity of the metal film layer to the display device area may be avoided, and the detection efficiency of the personnel may be improved.

Based on the same inventive concept, a display apparatus is also disclosed, which may include a display device area in the display substrate in any one of the above-mentioned embodiments.

The various embodiments in this specification are described in a progressive manner, with each embodiment focusing on the differences from the others. For the parts that are the same or similar between embodiments, reference should be made to each other.

Finally, it should be noted that in this document, relational terms such as “first” and “second” are used solely to distinguish one entity or operation from another, without necessarily requiring or implying any actual relationship or order between these entities or operations. Moreover, the terms “include,” “comprising,” or any other variations thereof are intended to encompass non-exclusive inclusion, so that a process, method, product, or device that includes a series of elements is not limited to those elements but also includes other elements that are not explicitly listed, or elements that are inherent to such a process, method, product, or device. Unless further restricted, elements limited by the phrase “including a . . . ” do not exclude the existence of additional identical elements in the process, method, product, or device that includes the said element.

The above provides a detailed introduction to a display substrate, a mask, and a vapor deposition system as disclosed in this document. Specific examples have been used to illustrate the principles and implementation methods of this disclosure. The descriptions of the embodiments are only intended to assist in understanding the methods and core ideas of this disclosure. At the same time, for ordinary technicians in this field, there will be changes in the specific implementation methods and application scope based on the ideas of this disclosure. In summary, the content of this specification should not be understood as a limitation on this disclosure.

After considering the specification and practicing the invention disclosed here, technicians in this field will easily think of other implementations of this disclosure. This disclosure is intended to cover any modifications, uses, or adaptive changes to this disclosure that follow the general principles of this disclosure and include common knowledge or conventional technical means in this technical field that are not disclosed in this disclosure. The specification and examples are only exemplary, and the true scope and spirit of this disclosure are indicated by the claims below.

It should be understood that this disclosure is not limited to the precise structures described and shown in the drawings above, and various modifications and changes can be made without departing from its scope. The scope of this disclosure is limited only by the claims appended hereto.

The terms “an embodiment,” “embodiment,” or “one or more embodiments” as used herein mean that the specific features, structures, or characteristics described in conjunction with the embodiment are included in at least one embodiment of this disclosure. Furthermore, please note that the phrase “in one embodiment” does not necessarily refer to the same embodiment.

In the specification provided here, a large number of specific details are described. However, it should be understood that the embodiments of this disclosure can be practiced without these specific details. In some instances, well-known methods, structures, and techniques are not shown in detail so as not to obscure the understanding of this specification.

In the claims, any reference numerals in parentheses should not be construed as limiting the claims. The word “comprising” does not exclude the presence of elements or steps not listed in the claims. The word “a” or “an” preceding an element does not exclude the presence of multiple such elements. This disclosure can be implemented using hardware with various components and by a computer appropriately programmed. In claims listing several apparatuses, some of these apparatuses may be embodied by the same hardware item. The use of ordinals such as first, second, and third does not indicate any order. These words can be interpreted as names.

Finally, it should be noted that the above examples are only used to illustrate the technical solution of this disclosure, not to limit it; although this disclosure has been described in detail with reference to the aforementioned examples, ordinary technicians in this field should understand that they can still modify the technical solutions recorded in the aforementioned examples or replace some technical features with equivalent substitutes; and these modifications or replacements do not deviate from the spirit and scope of the technical solutions of the embodiments of this disclosure.

1. A display substrate, comprising: a display device area, and a non-display device area adjacent to the display device area, and further comprising:
a light emitting device layer, located in the display device area;
at least one test unit, located in the non-display device area and distributed in a planar direction of the display substrate, the test unit comprising a plurality of measurement areas provided at intervals in the planar direction,
wherein each measurement area in one test unit is configured to test at least one layer located in the light emitting device layer, and the number of measurement areas in the at least one test unit is not less than the number of film layers comprised in the light emitting device layer.

2. The display substrate according to claim 1, further comprising: a substrate, a first electrode layer, and a pixel definition layer, wherein the first electrode layer is close to the substrate, and the pixel definition layer is located at a side of the first electrode layer facing away from the substrate,
wherein the pixel definition layer located in the display device area comprises a plurality of first openings arranged at intervals, and orthographic projections of the first openings on the substrate fall into an orthographic projection of the first electrode layer on the substrate;
the pixel definition layer located in the non-display device area comprises a plurality of second openings arranged at intervals, and the second openings form the measurement areas,
wherein the first electrode layer serves as an anode or a cathode in the light emitting device layer.

3. The display substrate according to claim 2, wherein the second opening is located at the side of the first electrode layer facing away from the substrate, and an orthographic projection of the second opening on the substrate falls into the orthographic projection of the first electrode layer on the substrate.

4. The display substrate according to claim 2, wherein a size of an orthographic projection of one of the second openings on the substrate is greater than a size of the orthographic projection of one of the first openings on the substrate.

5. The display substrate according to claim 2, wherein at least one of the measurement areas is provided with an emissive film layer in the light emitting device layer, and the display device area comprises a plurality of sub-pixels, wherein a size of an orthographic projection of the emissive film layer on the substrate is greater than a size of an orthographic projection of the sub-pixel on the substrate.

6. The display substrate according to claim 1, wherein the plurality of measurement areas are arranged in an array in the planar direction.

7. The display substrate according to claim 1, wherein the plurality of measurement areas comprise first measurement areas provided with first type film layers and second measurement areas provided with second type film layers, and the first measurement area is located at a side of the second measurement area facing away from the display device area.

8. The display substrate according to claim 7, wherein the first type film layers comprise a common film layer, and the second type film layers comprise an emissive layer.

9. The display substrate according to claim 7, wherein an orthographic projection of the first type film layer on a base of the display substrate completely covers the display device area, and an orthographic projection of the second type film layer on the base of the display substrate partially covers the display device area.

10. The display substrate according to claim 8, wherein the first type film layer comprises at least one of an electron injection layer, an electron transport layer, a hole injection layer, a hole transport layer, a hole barrier layer, an electron barrier layer, a charge generation layer, a second electrode layer, and a light extraction layer, and the second type film layer comprises the emissive layer and an auxiliary emissive layer.

11. The display substrate according to claim 7, wherein the number of measurement areas in the at least one test unit is greater than the number of film layers of the light emitting device layer,
wherein the plurality of measurement areas further comprise third measurement areas, and the third measurement areas are provided with a protective layer;
in the third measurement areas, the number of third measurement areas provided at the same side as the first measurement area is greater than the number of third measurement areas provided at the same side as the second measurement area.

12. The display substrate according to claim 1, wherein the at least one test unit is arranged in the non-display device area at equal intervals.

13. The display substrate according to claim 1, wherein the non-display device area comprises a first frame region and a second frame region oppositely provided in a first direction, and a plurality of test units are disposed in the first frame region and/or the second frame region;
the plurality of test units are symmetrically disposed in the first frame region and the second frame region, or
the plurality of test units are disposed in the first frame region and the second frame region, wherein a straight line parallel to the first direction passes through one test unit located in the first frame region or passes through one test unit located in the second frame region.

14. (canceled)

15.

16. The display substrate according to claim 13, wherein the plurality of test units are disposed in the first frame region and the second frame region, wherein a straight line parallel to the first direction simultaneously passes through one test unit located in the first frame region and one test unit located in the second frame region.

17. The display substrate according to claim 1, wherein a plurality of test units are provided in at least one side frame region of the non-display device area.

18. The display substrate according to claim 17, wherein the plurality of test units are disposed in a frame region close to a chip side of the display device area.

19. The display substrate according to claim 1, wherein the non-display device area comprises at least two magnetic force areas, and the test unit is located between the two magnetic force areas,
wherein an orthographic projection of the magnetic force area on a base does not overlap with an orthographic projection of the test unit on the base, and the magnetic force area is configured to adsorb a metal mask plate.

20. A mask plate, adapted to the display substrate according to claim 1, comprising:
a first area corresponding to a display device area on the display substrate; and
a second area corresponding to a non-display device area on the display substrate and comprising at least one sub-area, wherein the sub-area is arranged with an aperture corresponding to at least one of the measurement areas.

21. An evaporation system, comprising: a plurality of mask plates, and the display substrate according to claim 1,
wherein the mask plate comprises a first pattern corresponding to a display device area and a second pattern corresponding to a non-display device area, and the second pattern corresponds to at least one measurement area located in the non-display device area.

22. The evaporation system according to claim 21, wherein different mask plates have the same second pattern to jointly correspond to a plurality of measurement areas in the non-display device area; or different mask plates have different second patterns to be used separately for evaporating film layers corresponding to different measurement areas of the non-display device area.
